(19) United States
(12) Patent Application Publication
(10) Pub. No.: US 2026/0173339 A1
(43) Pub. Date: Jun. 18, 2026

(54) END-EFFECTOR, SUPPLY CART AND AUTOMATED ASSEMBLY STATION USING THE SAME

(71) Applicant: Wiwynn Corporation, New Taipei City (TW)

(72) Inventors: JUI-HUNG WENG, New Taipei City (TW); LI-HUAN JHANG, New Taipei City (TW); HSUAN CHIH LIN, New Taipei City (TW); CYUAN LEE, New Taipei City (TW); SHU CHING HSU, New Taipei City (TW); CHIA-HSIN HSIEH, New Taipei City (TW)

(21) Appl. No.: 19/207,470

(22) Filed: May 14, 2025

(30) Foreign Application Priority Data
Dec. 17, 2024 (TW) 113149141

(51) Int. Cl. H05K 13/00

(52) U.S. Cl. CPC H05K 13/0084

(57) ABSTRACT

A supply cart is configured to accommodate multiple trays to be taken out by a feeder. The supply cart includes a cabinet, multiple first drawer slides, multiple second drawer slides and multiple first reflectors. The multiple first drawer slides are fixed to one side of the cabinet. The multiple second drawer slides are fixed to an opposite side of the cabinet. One of multiple first drawer slides and one of the multiple second drawer slides are a pair of drawer slides configured to support one of the multiple trays. The multiple first reflectors are respectively disposed on the multiple first drawer slides, and configured to generate a first feedback signal corresponding to a sensing signal that is generated by a level sensor disposed on the feeder.

### CROSS-REFERENCE TO RELATED APPLICATIONS

This non-provisional application claims priority under 35 U.S.C. § 119(a) on Patent Application No(s). 113149141 filed in Taiwan, R.O.C. on Dec. 17, 2024, the entire contents of which are hereby incorporated by reference.

### TECHNICAL FIELD

The disclosure relates to an end-effector, a supply cart and an automated assembly station.

### BACKGROUND

Nowadays, automated assembly has been adopted in manufacturing electronic devices to prolong working hours with less human labor, improve manufacturing efficiency, standardize assembly operations to keep manufacturing quality. During a process of assembling an electronic device, a feeder takes out a tray holding materials stocked in a cart, and then the material is assembled together with another material, so as to manufacture the electronic device.

Considering size tolerances and variations among different carts, different types of materials, and floors where the carts stand on, a pitch between two trays in the cart should be large enough to ensure that the feeder can take out materials without any collision. However, increasing the pitch between two trays not only reduces the maximum number of trays that can be accommodated in the cart, but also reduces a quantity of materials that can be stocked in the cart, which decreases the efficiency of assembling electronic devices. In light of this, how to solve the aforementioned issue is one of the topics in this field.

### SUMMARY

The disclosure provides an end-effector, a supply cart and an automated assembly station which forms multiple serials and nonstop supply chains to facilitate assembly efficiency.

One embodiment of the disclosure provides a supply cart. The supply cart is configured to accommodate multiple trays to be taken out by a feeder. The supply cart includes a cabinet, multiple first drawer slides, multiple second drawer slides and multiple first reflectors. The multiple first drawer slides are fixed to one side of the cabinet. The multiple second drawer slides are fixed to an opposite side of the cabinet. One of multiple first drawer slides and one of the multiple second drawer slides are a pair of drawer slides configured to support one of the multiple trays. The multiple first reflectors are respectively disposed on the multiple first drawer slides, and configured to generate a first feedback signal corresponding to a sensing signal that is generated by a level sensor disposed on the feeder.

Another embodiment of the disclosure provides an automated assembly station. The automated assembly station includes a workbench, at least one aforementioned supply cart and at least one feeder. The supply cart is disposed adjacent to the workbench, and configured to stock at least one material. The feeder is disposed on the workbench, adjacent to the supply cart, and configured to feed the material from the supply cart to the workbench.

Still another embodiment of the disclosure provides an end-effector. The end-effector includes a bracket, a connector, a first pneumatic cylinder, a 6-axis force-torque sensor, an electronic compliance, an air impact gripper and a gripper. The connector is configured to connect the end-effector to the robot. The first pneumatic cylinder is configured to drive the gripper moving along a Z direction. The 6-axis force-torque sensor is configured to feedback force-torque signals to an industrial automation system. The electronic compliance is configured to correct positional errors. The air impact gripper is configured to drive the gripper to open and close. The gripper is connected to the air impact gripper, and configured to grip the material. At a first side of the bracket, the connector, the first pneumatic cylinder, the 6-axis force-torque sensor, the electronic compliance, the air impact gripper and the gripper are fixed to the bracket and stacked in order along a Z direction.

The end-effector, the supply cart and the automated assembly station have advantages as follows: (1) the automated assembly station includes two serial supply chains, one can be replenished when another one is supplying materials, keeping the automated assembly station nonstop; (2) the automated assembly station is capable of supply, scanning and installation to save human labor, improve manufacturing efficiency, and standardize assembly operations (3) the supply cart is equipped with reflectors so that the feeder can take out materials at certain levels according to feedback signals from the reflectors; and (4) the end-effector is integrated with multiple functional elements to perform various tasks. Therefore, the assembly efficiency of the electronic devices can be improved.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a perspective view of an automated assembly station according to one embodiment of the disclosure;

FIG. 2 is a top view of the automated assembly station in FIG. 1;

FIG. 3 is a perspective view of the supply cart in FIG. 1;

FIG. 4 is a partial perspective view of a feeder in FIG. 1;

FIG. 5 is a back view of a supply cart with an enlarged portion according to a first embodiment of the disclosure;

FIG. 6 is a flowchart of control process according to the first embodiment of the disclosure;

FIG. 7 is a back view of a supply cart according to a second embodiment of the disclosure;

FIG. 8 is a schematic view of a first reflector and a second reflector with two types of inclines according to the second embodiment of the disclosure;

FIG. 9 is a flowchart of control process according to the second embodiment of the disclosure;

FIG. 10 is a partial perspective view of the supply cart and a workbench in FIG. 1 separated from each other;

FIG. 11 is an exploded view of an end-effector 50 in FIG. 1;

FIG. 12 is a perspective view of the end-effector 50 in FIG. 11; and

FIG. 13 is a flowchart of an assembly process of the automated assembly station in FIG. 2.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

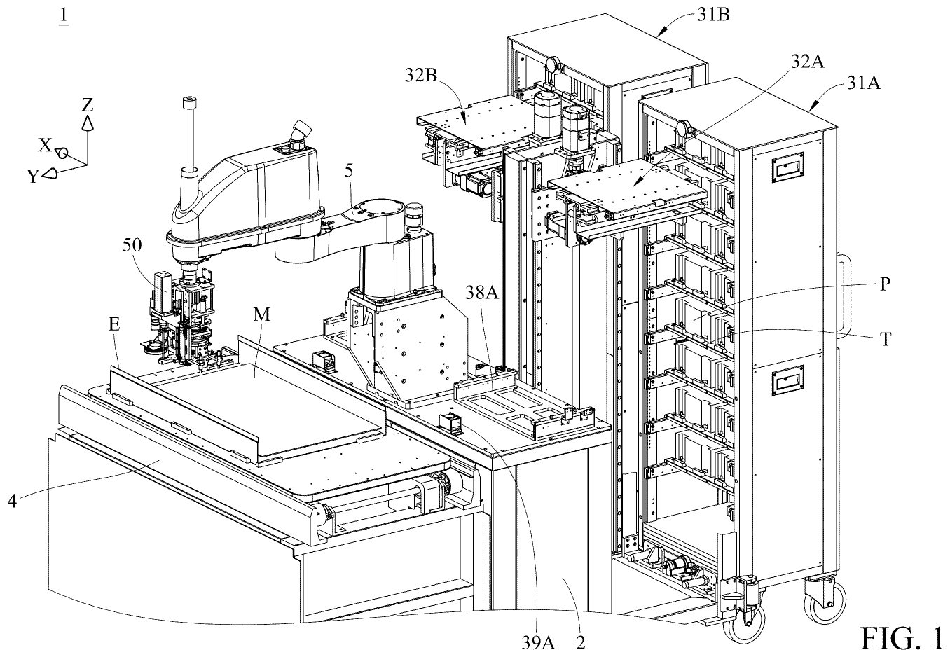

FIG. 1 is a perspective view of an automated assembly station 1 according to one embodiment of the disclosure. The automated assembly station 1 includes a workbench 2, at least one supply cart 31A, at least one feeder 32A, a conveyor 4 and a robot 5.

There are two supply carts 31A and 31B in the automated assembly station 1, the two supply carts 31A, 31B are structurally identical and arranged side by side. The supply cart 31A is disposed adjacent to the workbench 2, and configured to stock at least one material P, where the material P can be any component part such as an IC, graphics card or heatsink, etc. There are multiple trays T in the supply cart 31A, and at least one material P is stocked in one of the multiple trays T. There are two feeders 32A,32B corresponding to the two supply carts 31, the two feeders 32A, 32B are disposed on the workbench 2, adjacent to the supply carts 31A, 31B, and configured to feed the material P from the supply carts 31A, 31B to the workbench 2. The conveyor 4 is disposed adjacent to the workbench 2, and configured to convey an electronic device E or a semifinished product along X direction, where the electronic device E is, for example, a server.

The automated assembly station 1 further includes at least one holder 38A, 38B, disposed on the workbench 2, and configured to hold a tray T. There are two holders 38A, 38B in the automated assembly station 1 and corresponding to the two supply carts 31A, 31B. The automated assembly station 1 further includes at least one scanner 39A, 39B, disposed on the workbench 2, and configured to scan a barcode of the material P that is gripping by the robot 5. There are two holders 39A, 39B in the automated assembly station 1 and corresponding to the two supply carts 31A, 31B.

The robot 5 is disposed on the workbench 2 between the feeders 32A, 32B and the conveyor 4, and configured to grip the material P from the tray T, move the material P to the scanner 39A or 39B, the conveyor 4, and then install the material P into the electronic device E. The robot 5 is, for example, a SCARA robot or a 6-DOF robotic manipulator.

The automated assembly station 1 further includes an end-effector 50, installed on an outer arm of the robot 5, and configured to grip the material P and install the material P into a motherboard M of the electronic device E.

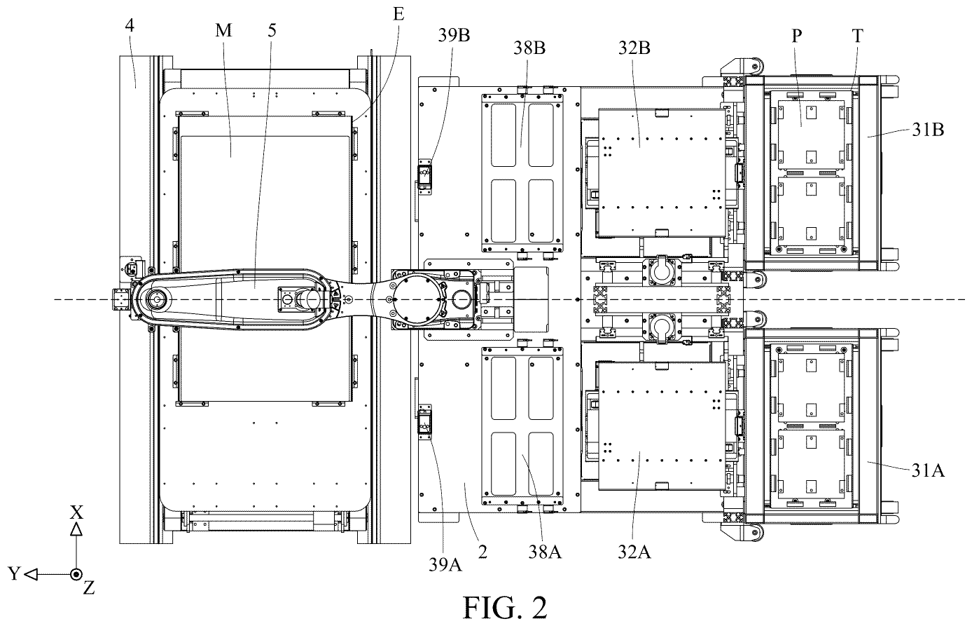

FIG. 2 is a top view of the automated assembly station 1 in FIG. 1. The automated assembly station 1 includes two serial supply chains that are symmetric about a centerline of the robot 5 and along the Y direction. In detail, the cart 31A, the feeder 32A, the holder 38A, the scanner 39A are serially arranged to form one serial supply chain at the A side; while the cart 31B, the feeder 32B, the holder 38B, the scanner 39B are serially arranged to form another serial supply chain at the B side. It should be noted that, when the supply cart 31A is supplying the material P by the feeder 32A, another supply cart 31B can be replenished by a staff or robot to keep the automated assembly station 1 nonstop, and vice versa.

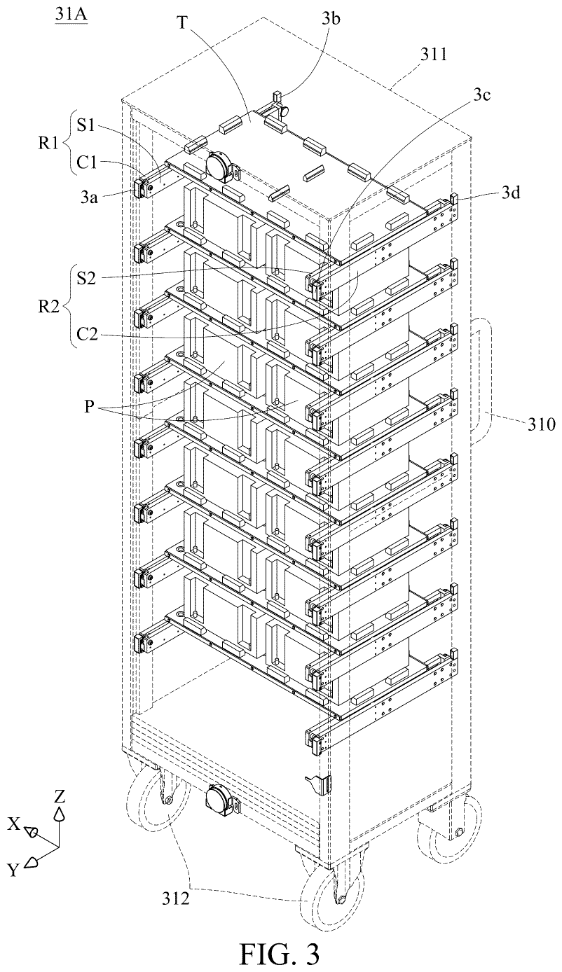

FIG. 3 is a perspective view of the supply cart 31A in FIG. 1. The supply cart 31A includes at least one handle 310, a cabinet 311, multiple wheels 312, multiple first drawer slides R1, multiple second drawer slides R2, the multiple trays T, and multiple first reflectors 3a.

The cabinet 311 is disposed on and fixed to the multiple wheels 312. The at least one handle 310 can be fixed to at least one column or a door of the cabinet 311. Therefore, the staff or robot may grip the at least one handle 310 to push, drag and move the supply cart 31.

The multiple first drawer slides R1 are fixed to one side of the cabinet 311, the multiple second drawer slides R2 are fixed to an opposite side of the cabinet 311, and one first drawer slide R1 and one second drawer slide R2 are a pair of drawer slides configured to support one of the multiple trays T. The multiple trays T can be drawn out from an opening or the door of the cabinet 311, so that the materials P can be replenished easily with more space. In the embodiment of FIG. 1 to FIG. 3, one tray T stocks two materials P; however, in other embodiments, one tray T stocks at least one material P. The first drawer slide R1 and the second drawer slide R2 are structurally symmetric. Each of the multiple first drawer slides R1 includes a first cabinet member C1 fixed to the cabinet 311, and a first slide member S1 engaged with the first cabinet member C1. Each of the multiple second drawer slides R2 includes a second cabinet member C2 fixed to the cabinet 311, and a second slide member S2 engaged with the second cabinet member C2.

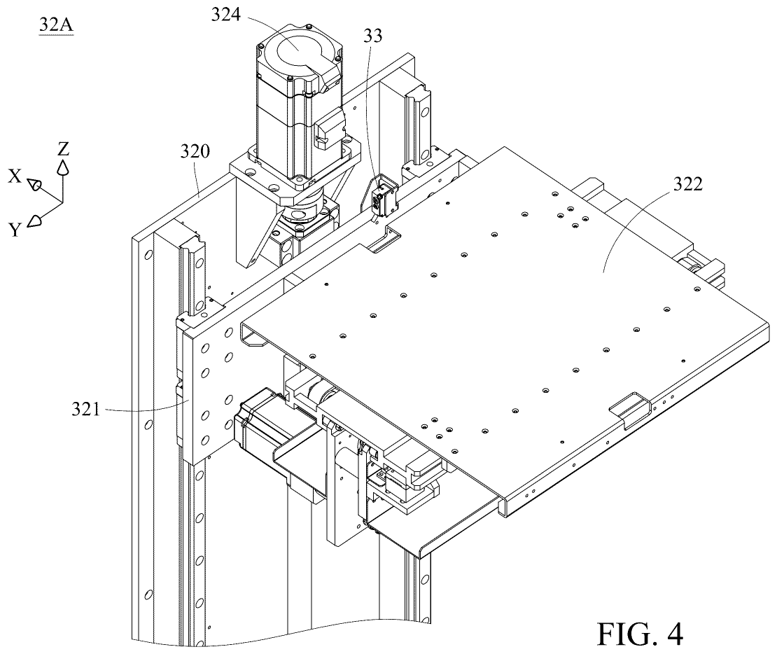

Each of the multiple first reflectors 3a is disposed on a back end of the first cabinet member C1, and configured to generate a first feedback signal corresponding to a sensing signal that is generated by a level sensor 33A of the feeder 32A (shown in FIG. 4).

In one embodiment, the supply cart 31A further includes multiple second reflectors 3b. Each of the multiple second reflectors 3b is disposed on a front end of the first cabinet member C1, disposed higher than the first reflector 3a along the Z direction, and configured to generate a second feedback signal corresponding to the sensing signal that is generated by the level sensor 33 of the feeder 32A.

In one embodiment, the supply cart 31 further includes multiple third reflectors 3c and multiple fourth reflectors 3d. Each of the multiple third reflectors 3c is disposed on a back end of the second cabinet member C2, and configured to generate a third feedback signal corresponding to a sensing signal that is generated by another level sensor the feeder 32B. Each of the multiple fourth reflectors 3d is disposed on a front end of the second cabinet member C2, disposed higher than the third reflector 3c along the Z direction, and configured to generate a fourth feedback signal corresponding to the sensing signal that is generated by another level sensor of the feeder 32B.

FIG. 4 is a partial perspective view of the feeder 32A in FIG. 1. The feeders 32A and 32B are structurally symmetric. The feeder 32A includes a column 320, a carriage motor 324, a carriage 321 and a shovel assembly 322, wherein the shovel assembly 322 is also known as a fork assembly. The column 320 is disposed on the workbench 2 and extends along the Z direction. The carriage 321 is engaged with a pair of rails of the column 320. The carriage motor 324 is fixed to a top of the column 320, connected to the carriage 321, and configured to drive the carriage 321 moving along the Z direction. The shovel assembly 322 is fixed to the carriage 321, and includes a shovel and a shovel motor. The shovel is configured to shovel out the tray T, and the shovel motor is configured to drive the shovel moving along the Y direction. The level sensor 33 is disposed on the carriage 321 of the feeder 32A, and configured to generate the sensing signal and receive the first feedback signal generated from at least one of the multiple first reflectors 3a.

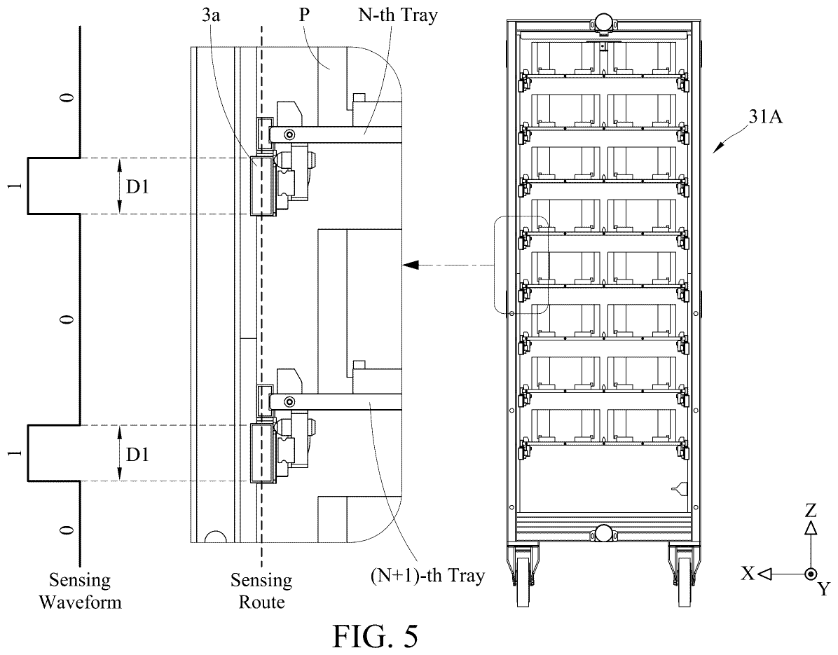

FIG. 5 is a back view of the supply cart 31A with an enlarged portion according to a first embodiment of the disclosure. In the first embodiment, the supply cart 31A is equipped with the multiple first reflectors 3a, i.e., the multiple reflectors 3b, 3c and 3d are omitted. Also, in the first embodiment, the supply cart 31B is equipped with the multiple third reflectors 3c, i.e., the multiple reflectors 3a, 3b and 3d are omitted. Nevertheless, to make the supply carts 31A and 31B be able to park at both the A and B sides, both the supply carts 31A, 31B are equipped with the multiple first reflectors 3a and the multiple third reflectors 3c, which is also applicable in the first embodiment.

When the carriage motor 324 drives the carriage 321 moving along the Z direction, the level sensor 33 emits the sensing signal along a sensing route and receives the first feedback signal. Meanwhile, a controller of the feeder 32A generates a sensing waveform according to the first feedback signal. In detail, the controller of the feeder 32A records a first state (logic 1) if the first feedback signal is received, and a second state (logic 0) if the first feedback signal is not received. A duration D1 of the first feedback signal equals to a height of the first reflector 3a. Therefore, by counting a number of the durations D1, which level the tray T lies can be determined. For example, given that the carriage 321 is moving from top to bottom, the tray T lies in N-th level is determined when N durations D1 are sensed by the level sensor 33 and accumulated by the controller.

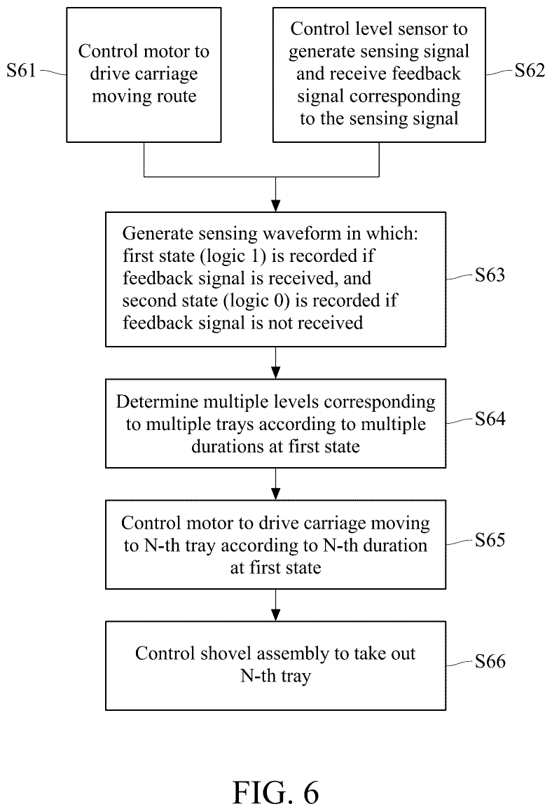

FIG. 6 is a flowchart of control process 60 according to the first embodiment of the disclosure. The control process 60 can be compiled into a program code instructing the controller of the feeder 32A or 32B to execute steps S61 to S66. In the control process 60, an initialization phase includes Steps S61 to S63, and an operating phase includes steps S64 to S66. In step S61, the controller controls the carriage motor 324 to drive the carriage 321 moving a route.

In step S62, the controller controls the level sensor 33 to generate the sensing signal and then receive the feedback signal corresponding to the sensing signal. In step S63, the controller generates a sensing waveform in which a first state (logic 1) is recorded if the feedback signal is received, and a second state (logic 0) is recorded if the feedback signal is not received. Note that the feedback signal is generated by the first reflector 3a when the control process 60 is executed by the controller of the feeder 32A; while the feedback signal is generated by the third reflector 3c when the control process 60 is executed by the controller of the feeder 32B.

In step S64, the controller determines multiple levels corresponding to the multiple trays T according to the multiple durations D1 at the first state. In step S65, the controller controls the carriage motor 324 to drive the carriage 321 moving to the N-th tray according to N-th duration at the first state (logic 1). For example, there are 8 trays T in the supply cart 31A in FIGS. 3A, 1≤N≤8, and N is a natural number not greater than a total number of the multiple trays T. If the feeder 32A is going to take out the 3rd tray T (i.e., N=3) from the top of the supply cart 31A, the controller of the feeder 32A controls the carriage motor 324 to drive the carriage 321 moving to the 3rd tray T when the 3rd duration D1 at the first state (logic 1) has been sensed. In step S66, the controller controls the shovel assembly 322 to take out the N-th tray T together with the material P. Note that the following operation of moving the tray T to the holder 38A is omitted herein.

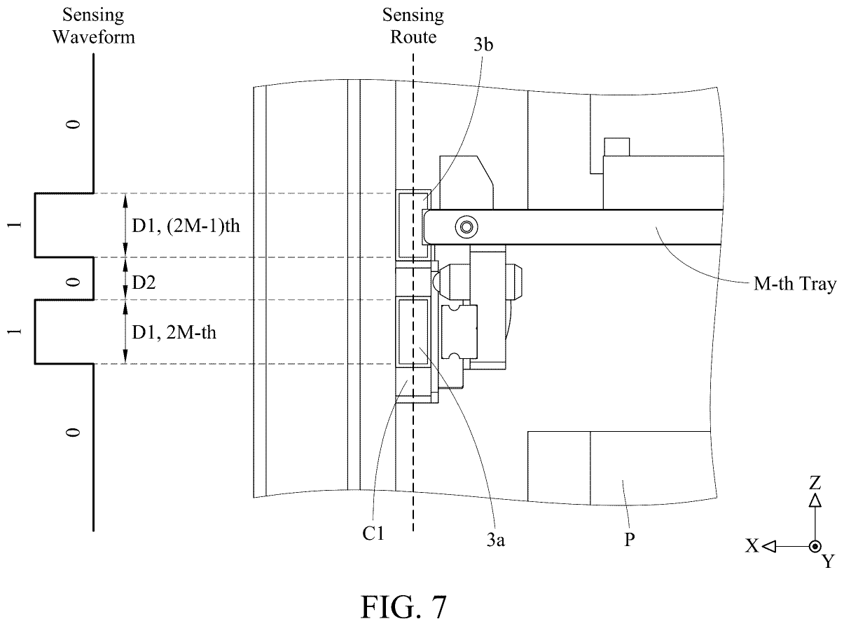

FIG. 7 is a back view of the supply cart 31A according to a second embodiment of the disclosure. In the second embodiment, the supply cart 31A is equipped with the multiple first reflectors 3a and the multiple second reflectors 3b, i.e., the multiple reflectors 3c, 3d are omitted. Also, in the second embodiment, the supply cart 31B is equipped with the multiple third reflectors 3c and the multiple fourth reflectors 3d, i.e., the multiple reflectors 3a, 3b are omitted. Nevertheless, to make the supply carts 31A, 31B be able to park at both the A, B sides, both the supply carts 31A, 31B are equipped with the multiple reflectors 3a, 3b, 3c and 3d, which is also applicable in the second embodiment.

When the carriage motor 324 drives the carriage 321 moving along the Z direction, the level sensor 33 emits the sensing signal along a sensing route and receives the first feedback signal. Meanwhile, the controller of the feeder 32A generates a sensing waveform according to the first feedback signal. In detail, the controller of the feeder 32A records a first state (logic 1) if the first feedback signal is received, and a second state (logic 0) if the first feedback signal is not received. The duration D1 of the first feedback signal equals to the height of the first reflector 3a. Therefore, by counting a number of the durations D1, which level the tray T lies can be determined. For example, given that the carriage 321 is moving from top to bottom, the tray T lies in M-th level is determined when 2M durations D1 are sensed by the level sensor 33 and accumulated by the controller. Note that the 2M-th duration D1 corresponds to the 2M-th first reflector 3a and the (2M−1)th duration D3 corresponds to the (2M−1)th second reflector 3b. A duration D2 at the second state (logic 0) is between the 2M-th and (2M−1)th durations D1 at the first state (logic 1).

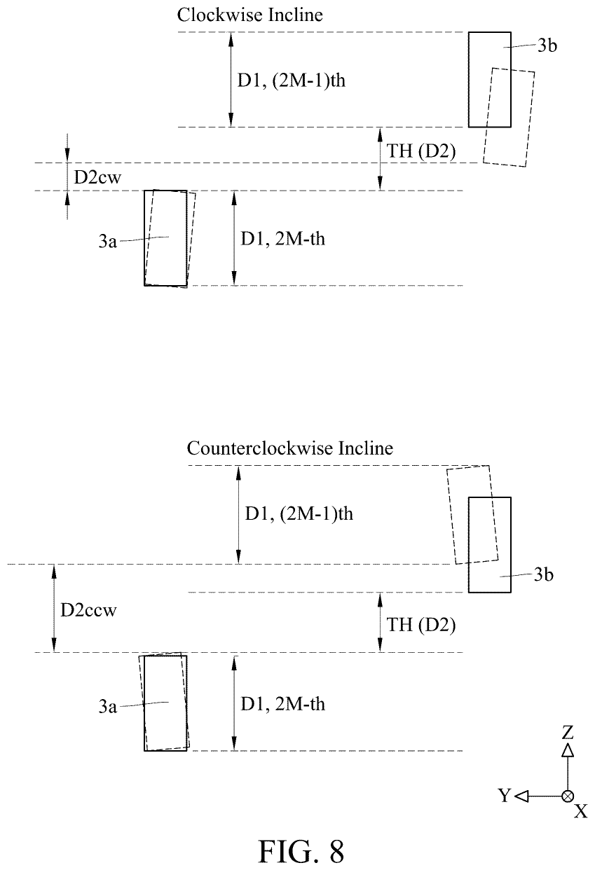

FIG. 8 is a schematic view of the first reflector 3a and the second reflector 3b with two types of inclines according to the second embodiment of the disclosure. If the supply cart 31A inclined clockwise, an inclined duration D2cw is smaller than a threshold TH (e.g., the duration D2 in FIG. 7). On the other hand, if the supply cart 31A inclined counterclockwise, an inclined duration D2ccw is greater than the threshold TH. In other words, the incline is detected if the duration D2cw or D2ccw between the 2M-th and (2M−1)th durations D1 is outside of the threshold TH. In the second embodiment, the second duration D2 is a distance between the first reflector 3a and the second reflector 3b along the Z direction, and the threshold TH equals the duration D2. However, in various embodiments, the threshold TH may be the duration D2 plus or minus a tolerance.

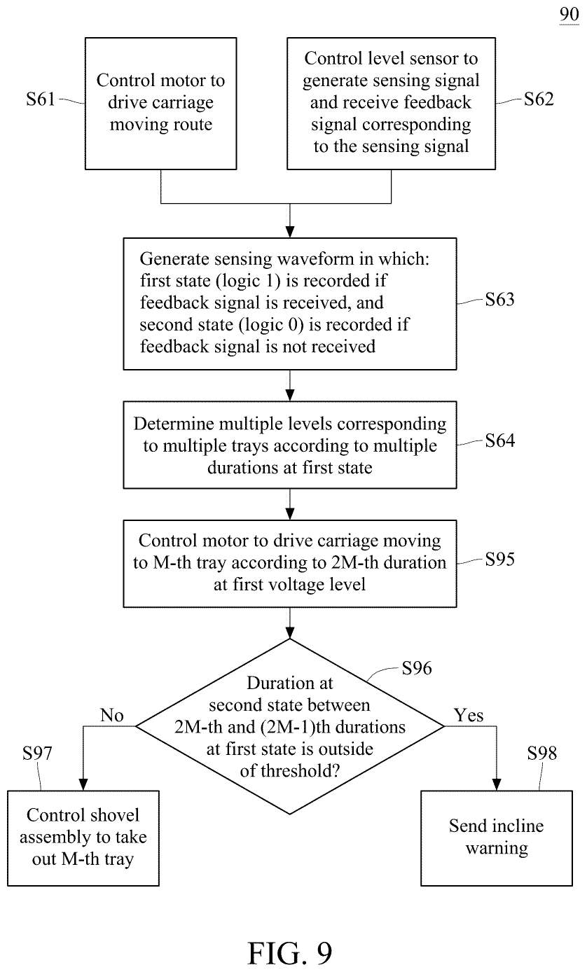

FIG. 9 is a flowchart of control process 90 according to the second embodiment of the disclosure. The control process 90 can be compiled into a program code instructing the controller of the feeder 32A or 32B to execute steps S61 to S64, S95 to S98. In the control process 90, the initialization phase includes Steps S61 to S63, and an operating phase includes steps S64, S95 to S98. Details regarding steps S61 to S64 can be obtained by referring to the descriptions regarding FIG. 6.

In step S95, the controller controls the carriage motor 324 to drive the carriage 321 moving to the M-th tray according to the 2M-th duration at the first state (logic 1). For example, there are 8 trays T in the supply cart 31A in FIGS. 3, 1≤M≤8, and M is a natural number. If the feeder 32A is going to take out the 3rd tray T (i.e., M=3) from the top of the supply cart 31A, the controller of the feeder 32A controls the carriage motor 324 to drive the carriage 321 moving to the 3rd tray T when the 6th duration D1 at the first state (logic 1) has been sensed. Note that the 6th duration D1 corresponds to the 6th first reflector 3a and the 5th duration D1 corresponds to the 5th second reflector 3b.

In step S96, the controller determines if a duration D2 at the second state (logic 0) between the 2M-th and (2M−1)th durations D1 at the first state (logic 1) is outside of the threshold TH. In step S97, if the duration D2 at the second state (logic 0) is not outside of the threshold TH, the controller controls the shovel assembly 322 to take out the M-th tray. In step S98, if the duration D2 at the second state (logic 0) is outside of the threshold TH, the controller sends a notification to the industrial automation system to notify a warning to the staff.

By disposing the first reflector 3a and the second reflector 3b on one first drawer slide R1, an incline about the Y direction can be detected when the supply cart 31A is parked at the A side. Similarly, by disposing the third reflector 3c and the fourth reflector 3d on one second drawer slide R2, the incline about the Y direction can be detected when the supply cart 31B is parked at the B side.

In the first and second embodiments, the level sensor 33 is a retro-reflective optical sensor. However, other types of the level sensor 33 and the corresponding reflectors 3a, 3b, 3c and 3d may be applicable. For example, the level sensor 33 may be a contrast-type optical sensor, a diffuse reflection optical sensor, an ultrasonic emitter, or a proximity sensor, while the reflectors 3a, 3b, 3c and 3d may be modified correspondingly.

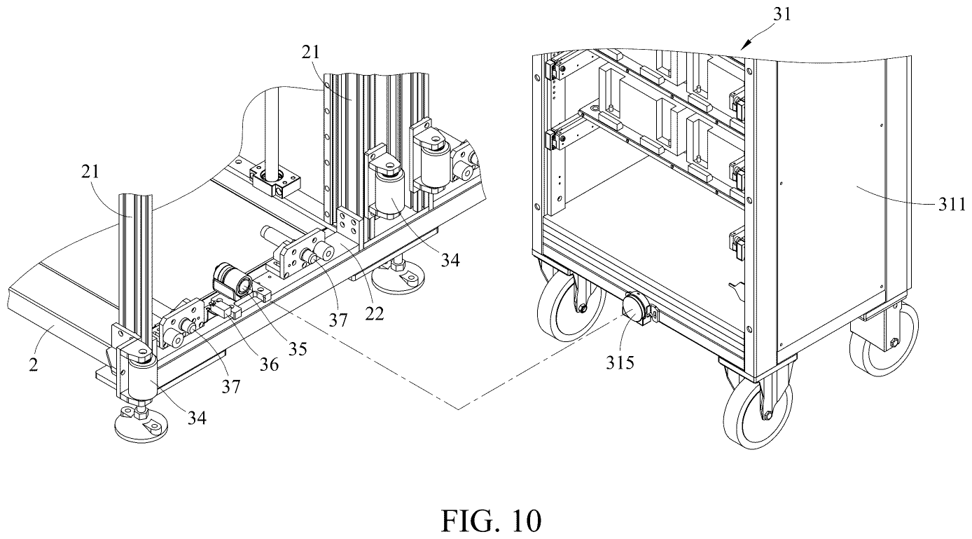

FIG. 10 is a partial perspective view of the supply cart 31 and the workbench 2 in FIG. 1 separated from each other. The workbench 2 further includes multiple guide wheels 34 disposed on multiple uprights 21 of the workbench 2, and the cabinet 311 can be parked between a pair of the guide wheels 34. In addition, the supply cart 31 further includes a second positioner 315 disposed on a bottom floor of the cabinet 311, and the workbench 2 includes a first positioner 35 disposed on a bottom bar 22 of the workbench 2. The first positioner 35 cooperates with the second positioner 315 to guide the cabinet 311 parking between the pair of the guide wheels 34. In one embodiment, the second positioner 315 and the first positioner 35 are magnetic positioners, and the first positioner 35 can be an electromagnet with adjustable magnetic force.

The workbench 2 further includes a presence sensor 36 disposed on the bottom bar 22 of the workbench 2, and configured to sense a presence of the cabinet 311. In one embodiment, the presence sensor 36 is an optical sensor. When the presence sensor 36 is covered by the supply cart 31, the presence sensor 36 transmits a signal to the industrial automation system to notify the presence of the cabinet 311, wherein the industrial automation system is a software that receives sensing signals and network packets to gather manufacturing data and send notifications to the staff. Meanwhile, once the first positioner 35 on the workbench 2 has attracted to the second positioner 315 on the supply cart 31, the first positioner 35 transmits a signal to the industrial automation system to notify that the supply cart 31 is in place.

The workbench 2 further includes multiple buffers 37 disposed on the bottom bar 22 of the workbench 2 and configured to absorb an impact from the cabinet 311 when the second positioner 315 is attracted to the first positioner 35. Two buffers 37 are disposed at two sides of the first positioner 35 to balance impact absorption. In one embodiment, the buffer 37 can be a hydraulic buffer, pneumatic shock absorber or spring damper, etc.

In some other embodiments, the guide wheels 34, the first positioner 35 and the buffer 37 may be disposed at the top of the workbench 2, and the second positioner 315 may be disposed at the top of the cabinet 311. In one embodiment, the top and the bottom of the workbench 2 each may be provided with the guide wheels 34, the first positioner 35 and the buffer 37, and the bottom and the top of the cabinet 311 each may be provided with the second positioner 315. In practice, the automated assembly station 1 is built within a cubicle, the second positioner 315 disposed at the top of the cabinet 311 can be attracted to a first positioner 35 disposed at a beam of the cubicle, which enhances attraction and firmness between the workbench 2 and the supply cart 31. It should be understood that the guide wheels 34, the second positioner 315, the first positioner 35, the presence sensor 36 and the buffer 37 are optional components and may be omitted in other embodiments.

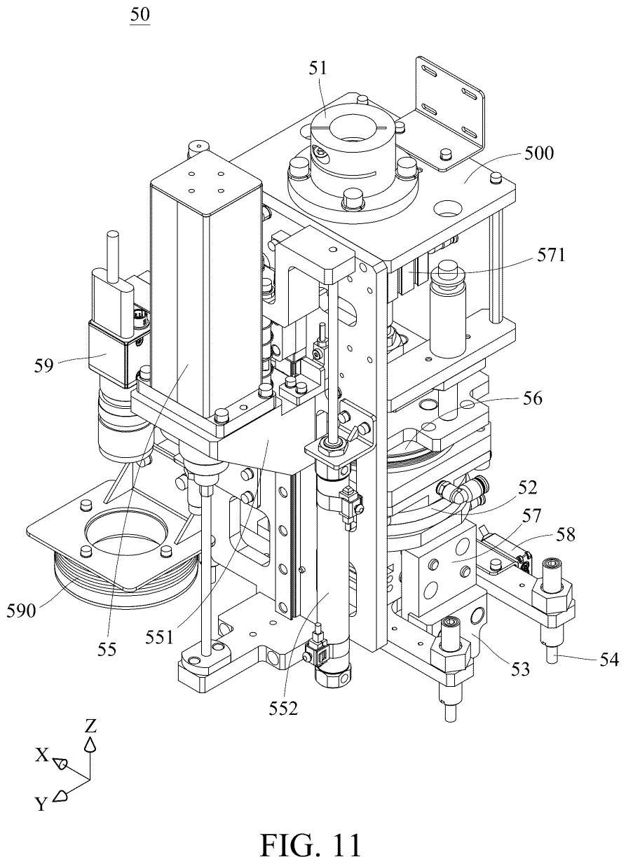

FIG. 11 is an exploded view of the end-effector 50 in FIG. 1. The end-effector 50 includes a bracket 500, a connector 51, a first pneumatic cylinder 571, a 6-axis force-torque sensor 56, an electronic compliance 52, an air impact gripper 57, a gripper 53, multiple spring plungers 54, multiple catch bolts 540, a presence sensor 58, an electric screwdriver 55, a carriage 551, a second pneumatic cylinder 552, a machine vision module 59 and a light source 590. The bracket 500 is configured to fix and integrate the abovementioned elements of the end-effector 50 altogether.

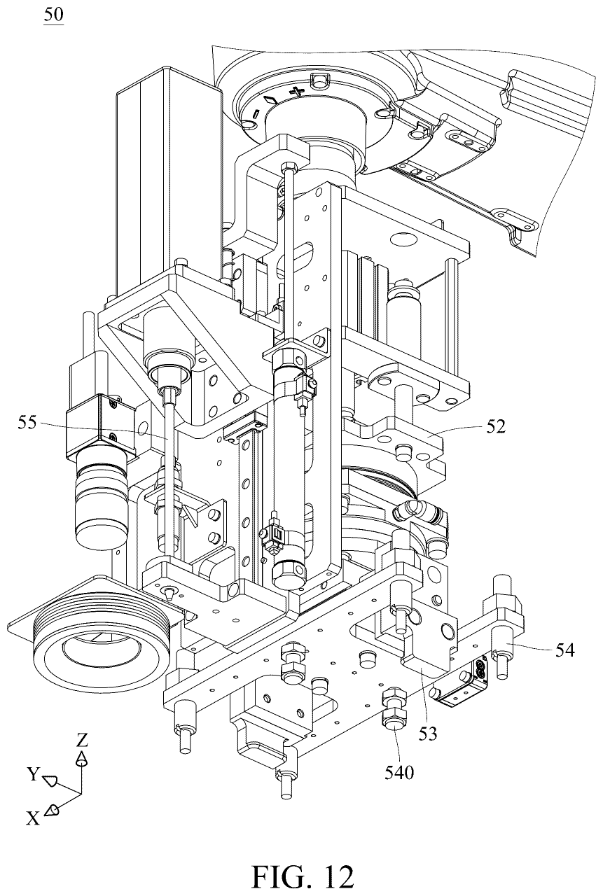

FIG. 12 is a perspective view of the end-effector 50 in FIG. 11. At a first side of the bracket 500, the connector 51, the first pneumatic cylinder 571, the 6-axis force-torque sensor 56, the electronic compliance 52, the air impact gripper 57 and the gripper 53 are stacked in order along the Z direction. The connector 51 is configured to connect the end-effector 50 to the robot 5. The first pneumatic cylinder 571 is configured to drive the gripper 53 moving along the Z direction. The 6-axis force-torque sensor 56 is configured to feedback force-torque signals to the industrial automation system. The electronic compliance 52 is configured to correct positional errors. The air impact gripper 57 is configured to drive the gripper 53 to open and close. The gripper 53 is connected to the air impact gripper 57, and configured to grip the material P. The multiple spring plungers 54 are disposed around the gripper 53, and configured to mitigate a swing of the material P during movement. Each of the multiple catch bolts 540 is disposed between two of the spring plungers 54, and configured to limit a swing range of the material P. The presence sensor 58 is disposed adjacent to the gripper 53, and configured to sense a presence of the material P.

At a second side of the bracket 500, the carriage 551 is engaged with a rail of the bracket 500, and configured to carry the electric screwdriver 55. The second pneumatic cylinder 552 is fixed to the bracket 500, connected to the carriage 551, and configured to drive the carriage 551 together with the electric screwdriver 55 moving along the Z direction. The electric screwdriver 55 is configured to fasten screws to fix the material P in the electronic device E. The machine vision module 59 is configured to detect targets through image recognition. The light source 590 is fixed to the bracket 500, disposed below the machine vision module 59, and configured to provide lighting for a clearer image quality. The electric screwdriver 55 is disposed between the second pneumatic cylinder 552 and the machine vision module 59. In one embodiment, the electric screwdriver 55 is a servo screwdriver.

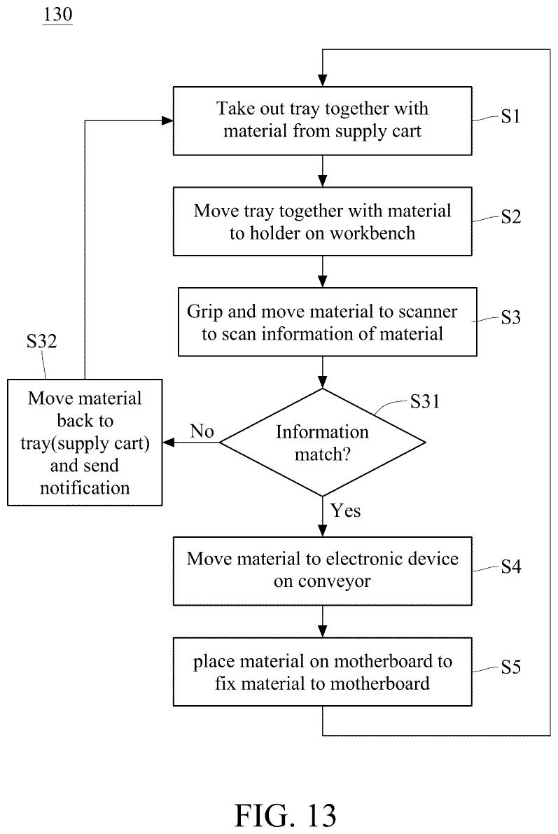

FIG. 13 is a flowchart of an assembly process 130 of the automated assembly station 1 in FIG. 2. The assembly process 130 can be compiled into program code(s) that is executed by a centralized master processor or multiple distributed slave processors of any devices in the automated assembly station 1. FIG. 13 in conjunction with FIG. 2 and FIG. 12, given that the feeder 32A is going to take out the material P from the top to bottom of the supply cart 31A.

In step S1, the feeder 32A performs the control process 60 or 90 to take out the top tray T together with the material P from the supply cart 31A. If the incline of the supply cart 31A is detected during the control process 90, the feeder 32A sends a notification to the industrial automation system to notify a warning to the staff.

In step S2, the feeder 32A moves the top tray T together with the material P to the holder 38 on the workbench 2. Step S2 includes the carriage motor 324 driving the carriage 321 moving along the Z direction to the level where the holder 38 locates, and the shovel assembly 322 placing the tray T on the holder 38.

In step S3, the gripper 53 grips and moves the material P on the tray T to scan information of the material P. Before gripping the material, the robot 5 approaches above the holder 38 and the first pneumatic cylinder 571 drops down the gripper 53.

In step S31, the scanner 39A scans a barcode located at a bottom of the material P, and determines if the information (e.g., part number, serial number, etc.) of the barcode matches with a default information. In step S32, if the information of the barcode does not match with the default information, the robot 5 moves the material P back to the holder 38 and the gripper 53 places the material P on the tray T, and then the industrial automation system sends a warning to notify the staff.

In step S4, if information of the barcode matches with the default information, the robot 5 moves the material P to the electronic device E, and the first pneumatic cylinder 571 drops down the gripper 53 to place the material P on the motherboard M. In step S5, the electric screwdriver 55 fastens the screws to fix the material P to the motherboard M. Afterwards, the assembly process 130 returns to step S1 to install the next material P. When the supply cart 31A is about to run out of stock, the feeder 32B is activated to be ready for supplying the material P. Therefore, the assembly efficiency of the electronic devices can be improved.

To sum up, the end-effector, the supply cart and the automated assembly station have advantages as follows: (1) the automated assembly station includes two serial supply chains, one can be replenished when another one is supplying materials, keeping the automated assembly station nonstop; (2) the automated assembly station is capable of supply, scanning and installation to save human labor, improve manufacturing efficiency, and standardize assembly operations (3) the supply cart is equipped with reflectors so that the feeder can take out materials at certain levels according to feedback signals from the reflectors; and (4) the end-effector is integrated with multiple functional elements to perform various tasks. Therefore, the assembly efficiency of the electronic devices can be improved.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A supply cart, configured to accommodate multiple trays to be taken out by a feeder, comprising:
a cabinet;
multiple first drawer slides fixed to one side of the cabinet;
multiple second drawer slides fixed to an opposite side of the cabinet, wherein one of multiple first drawer slides and one of the multiple second drawer slides are a pair of drawer slides configured to support one of the multiple trays; and
multiple first reflectors respectively disposed on the multiple first drawer slides, and configured to generate a first feedback signal corresponding to a sensing signal that is generated by a level sensor disposed on the feeder.

2. The supply cart according to claim 1, wherein each of the multiple first drawer slides comprises a first cabinet member fixed to the cabinet, and a first slide member engaged with the first cabinet member, wherein each of the multiple first reflectors is respectively disposed on a back end of the first cabinet member.

3. The supply cart according to claim 2, wherein the supply cart is parked adjacent to a workbench, and the feeder comprises:
a column disposed on the workbench and extending along a Z direction;
a carriage engaged with a pair of rails of the column, wherein the level sensor is disposed on the carriage;
a carriage motor fixed to a top of the column, connected to the carriage, and configured to drive the carriage moving along the Z direction; and
a shovel assembly fixed to the carriage, and comprising:
a shovel configured to shovel out the; and
a shovel motor configured to drive the shovel moving along a Y direction.

4. The supply cart according to claim 3, wherein the feeder further comprises a controller configured to perform a control process comprising:
step 1) controlling the carriage motor to drive the carriage moving a route;
step 2) controlling the level sensor to generate the sensing signal and then receive the first feedback signal corresponding to the sensing signal;
step 3) generating a sensing waveform, wherein a first state is recorded if the first feedback signal is received, and a second state is recorded if the first feedback signal is not received; and
step 4) determining multiple levels corresponding to the multiple trays according to multiple first durations at the first state.

5. The supply cart according to claim 4, wherein the control process further comprises:
step 5a) controlling the carriage motor to drive the carriage moving to an N-th tray of the multiple trays according to an N-th duration at the first state, where N is a natural number not greater than a total number of the multiple trays; and
step 6a) controlling the shovel assembly to take out the N-th tray.

6. The supply cart according to claim 4, further comprising:
multiple second reflectors configured to generate a second feedback signal corresponding to the sensing signal, wherein each of the multiple second reflectors is respectively disposed on a front end of the first cabinet member of each of the multiple first drawer slides.

7. The supply cart according to claim 6, wherein the control process further comprises:
step 5b) controlling the carriage motor to drive the carriage moving to an M-th tray of the multiple trays according to a 2M-th duration at the first state, where M is a natural number not greater than the total number of the multiple trays;
step 6b) determining if a second duration at the second state between the 2M-th and (2M−1)th durations at the first state is outside of a threshold;
step 7) controlling the shovel assembly to take out M-th tray if the second duration at the second state between the 2M-th and (2M−1)th durations at the first state is not outside of the threshold; and
step 8) sending an incline warning if the second duration at the second state between the 2M-th and (2M−1)th durations at the first state is outside of the threshold.

8. The supply cart according to claim 7, wherein the second duration is a distance between the first reflector and the second reflector along the Z direction, and the threshold equals the second duration, the second duration plus or minus a tolerance.

9. The supply cart according to claim 2, wherein each of the multiple second drawer slides includes a second cabinet member fixed to the cabinet, and a second slide member combined with the cabinet member, wherein each of the multiple second reflectors is respectively disposed on a back end of the first cabinet member of each of the multiple first drawer slides.

10. The supply cart according to claim 9, further comprising:
multiple third reflectors respectively disposed on a back end of the second cabinet member; and
multiple fourth reflectors respectively disposed on a front end of the second cabinet member.

11. The supply cart according to claim 1, wherein the workbench comprises:
multiple uprights;
multiple guide wheels disposed on of the multiple uprights;
a bottom bar connected to the multiple uprights; and
a first positioner disposed on the bottom bar, and configured to cooperate with a second positioner of the supply cart to guide the cabinet parking between the multiple guide wheels;
wherein the first positioner and the second positioner are either an electromagnet or a magnet.

12. The supply cart according to claim 11, wherein the workbench comprises:
a presence sensor disposed on the bottom bar, and configured to sense a presence of the cabinet.

13. The supply cart according to claim 11, wherein the workbench comprises:
multiple buffers disposed on the bottom bar, and configured to absorb an impact from the cabinet when the second positioner is attracted to the first positioner, wherein two of the multiple buffers are disposed at two sides of the first positioner to balance impact absorption.

14. The supply cart according to claim 1, wherein the multiple first reflectors are mirrors, and the level sensor is a retroreflection-type optical sensor.

15. An automated assembly station, comprising:
a workbench;
at least one supply cart of claim 1 disposed adjacent to the workbench, and configured to stock at least one material; and
at least one feeder disposed on the workbench, adjacent to the at least one supply cart, and configured to feed the at least one material from the at least one supply cart to the workbench.

16. The automated assembly station according to claim 15, further comprising:
at least one holder disposed on the workbench, adjacent to the at least one feeder, and configured to hold a tray stocking the at least one material;
at least one scanner disposed on the workbench, adjacent to the at least one holder, and configured to scan a barcode of the at least one material;
a conveyor disposed adjacent to the workbench, and configured to convey an electronic device; and
a robot disposed on the workbench, and configured to install the at least one material into the electronic device.

17. The automated assembly station according to claim 16, comprising two serial supply chains that are symmetric about a centerline of the robot and along a Y direction, wherein each of the two serial supply chains comprises one of the at least one supply cart, one of the at least one feeder, one of the at least one holder, and one of the at least one scanner.

18. An end-effector, adapted to a robot, comprising:
a bracket;
a connector configured to connect the end-effector to the robot;
a first pneumatic cylinder configured to drive the gripper moving along a Z direction;
a 6-axis force-torque sensor configured to feedback force-torque signals to an industrial automation system;
an electronic compliance configured to correct positional errors;
an air impact gripper configured to drive a gripper to open and close; and
the gripper connected to the air impact gripper, and configured to grip the material;
wherein, at a first side of the bracket, the connector, the first pneumatic cylinder, the 6-axis force-torque sensor, the electronic compliance, the air impact gripper and the gripper are fixed to the bracket and stacked in order along a Z direction.

19. The end-effector according to claim 18, further comprising:
multiple spring plungers disposed around the gripper, and configured to mitigate a swing of the material during movement;
multiple catch bolts, each of the multiple catch bolts is disposed between two of the spring plungers, and configured to limit a swing range of the material; and
a presence sensor disposed adjacent to the gripper, and configured to sense a presence of the material.

20. The end-effector according to claim 18, further comprising:
an electric screwdriver;
a carriage engaged with a rail of the bracket, and configured to carry the electric screwdriver;
a second pneumatic cylinder fixed to the bracket, connected to the carriage, and configured to drive the carriage together with the electric screwdriver moving along the Z direction;
a machine vision module fixed to the bracket, configured to detect targets through image recognition; and
a light source fixed to the bracket, disposed below the machine vision module, and configured to provide lighting;
wherein, at a second side of the bracket, the electric screwdriver is disposed between the second pneumatic cylinder and the machine vision module.
